(19) United States
(12) Patent Application Publication
(10) Pub. No.: US 2010/0014231 A1
(43) Pub. Date: Jan. 21, 2010

(54) BLADE ENCLOSURE WITH ID CASE

(75) Inventor: HAI-LONG ZHANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (SHENZHEN) CO., LTD., Shenzhen City (CN); HON HAI PRECISION INDUSTRY CO., LTD., Tu-Cheng (TW)

(21) Appl. No.: 12/347,330

(22) Filed: Dec. 31, 2008

(30) Foreign Application Priority Data
Jul. 16, 2008 (CN) 200820301530.X

(51) Int. Cl. H05K 5/02

(52) U.S. Cl. 361/679.02

(57) ABSTRACT

A blade enclosure includes a chassis comprising a sidewall and a front wall substantially perpendicular to the sidewall, a mounting bracket secured on the sidewall of the chassis, a bezel secured to the front wall of the chassis, the bezel comprising a panel substantially parallel to the front wall of the chassis and a side plate connected to the panel. An opening is defined at a joint of the panel and the side plate, and an ID case substantially parallel to the sidewall of the chassis is insertable in the chassis from the opening, the ID case having an information piece and a mounting piece received in the mounting bracket and slide therein. An end of the information piece aligned with an outer surface of the panel of the bezel is capable of being exposed outside from the opening of the bezel.

### BACKGROUND

1. Technical Field

The present disclosure relates to blade enclosures and, particularly, to a blade enclosure with an ID case.

2. General Background

Servers are widely used for delivering basic services to computer devices in a network and providing the sharing of resources. Blade servers have become popular due to advantages in space, power consumption, cable reduction, and reliability. A typical blade server system includes a server enclosure and a plurality of blades inserted in the server enclosure. Each of the blades may be dedicated to a single task different from the others, such as switching, routing, storage, storage area network, and fibre-channel access. However, it is difficult for users to identify a particular blade for maintenance and management, when so many blades are kept in a server enclosure.

What is needed, therefore, is a blade enclosure that allows easy identification of a blade received therein.

### BRIEF DESCRIPTION OF THE DRAWINGS

FIG. 1 is an exploded, isometric view of one embodiment of a blade enclosure with an ID case.

FIG. 2 is an assembled, isometric view of the blade enclosure of FIG. 1, with the ID case being pulled out.

FIG. 3 is an assembled view of FIG. 1.

FIG. 4 is similar to FIG. 3, but viewed from another aspect.

### DETAILED DESCRIPTION OF THE EMBODIMENTS

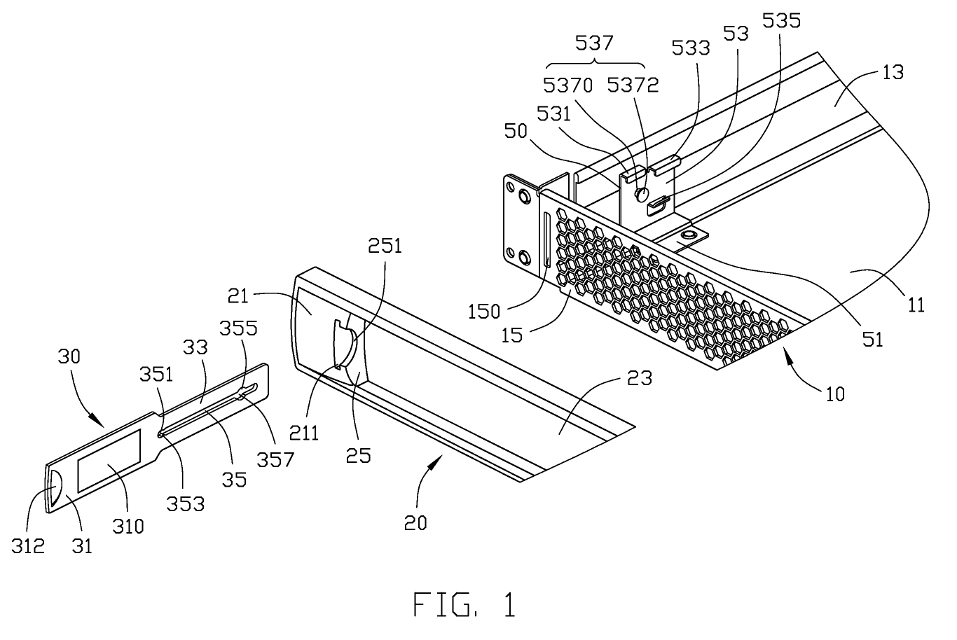

Referring to FIG. 1, one embodiment of a blade enclosure includes a chassis 10, a bezel 20 secured on a front end of the chassis 10, and a sheeted identification (ID) case 30 for identifying a function of a blade server.

The chassis 10 includes a bottom wall 11, a sidewall 13 substantially perpendicular to the bottom wall, and a front wall 15 substantially perpendicular to the bottom wall 11 and the sidewall 13. An L-shaped mounting bracket 50 spaced from the front wall 15 is mounted in the chassis 10. The mounting bracket 50 includes a bottom plate 51 secured on the bottom wall 11 of the chassis 10, and a side plate 53 abutting against the sidewall 13 of the chassis 10. Two bent tabs 531, 533 extend down from a top edge of the side plate 53 of the mounting bracket 50. A supporting tab 535 opposite to the bent tabs 533 extends from the side plate 53. The supporting tab 535 and the bent tabs 531, 533 cooperatively define a sliding channel therebetween. A securing post 537, located in the sliding channel, extends from the side plate 53. The securing post 537 includes a cylindrical sliding portion 5370 and a rounded blocking portion 5372. A first slot 150 is defined in the front wall 15 and aligned with the sliding channel defined by the bent tabs 531, 533 and the supporting tab 535. A plurality of heat dissipating holes (not labeled) may be defined adjacent to the sliding slot 150 to define a heat dissipating area.

The bezel 20 is configured to cover the front wall 15 of the chassis 10. The bezel 20 includes a panel 21 substantially parallel to the front wall 15 of the chassis 10, and an opening 23 defined therein. The opening 23 corresponds to the heat dissipating area of the front wall 15 to allow heat generated in the server to be dissipated therefrom. A side plate 25 is connected to one side of the front panel 21 and adjacent to the opening 23. A second slot 211 is defined in the front panel 21 corresponding to the first slot 150 in the front wall 15 of the chassis 10. An arc-shaped cutout 251 communicating with the second slot 211 is defined at a joint of the front panel 21 and the side plate 25.

The ID case 30 includes a substantially rectangular information piece 31. A width of the information piece 31 is substantially equal to the length of the second slot 211 in the bezel 20 and the first slot 150 in the front wall 15 of the chassis 10. A substantially rectangular information adhering area 310 is positioned in a middle portion of the information piece 31 for adhering information of the server thereon. An arc-shaped recessed operating piece 312 is defined at one end of the information piece 31. A substantially rectangular mounting piece 33 narrower than the information piece 31 extends from the other end thereof. A width of the mounting piece 33 is substantially equal to the distance between the bent tab 533 and the supporting tab 535. A thin and long sliding slot 35 is defined in a middle portion of the mounting piece 33 for the securing post 537 to slide therein. An arc-shaped receiving portion 351 is defined at a first end of the sliding slot 33 adjacent to the information piece 31. Two blocking protrusions 353 respectively extend from opposite edges of the sliding slot 35 adjacent to the receiving portion 351. A distance between the two blocking protrusions 353 is substantially equal to a diameter of the sliding portion 5370 of the securing post 537 so that the sliding portion 5370 can be blocked in the receiving portion 351 of the sliding slot 35 due to friction when the ID case 30 is mounted in the blade enclosure. Two opposite arc-shaped cutouts 355 are defined at edges of the sliding slot 35 adjacent to a second end of the sliding slot 35 thereby defining an installing area 357 allowing the blocking portion 5372 of the securing post 537 to engage in the sliding slot 35 therefrom. The diameter of the blocking portion 5372 is greater than the distance between the two cutouts 355 to prevent the blocking portion 5372 from disengaging from the sliding slot 35 during sliding.

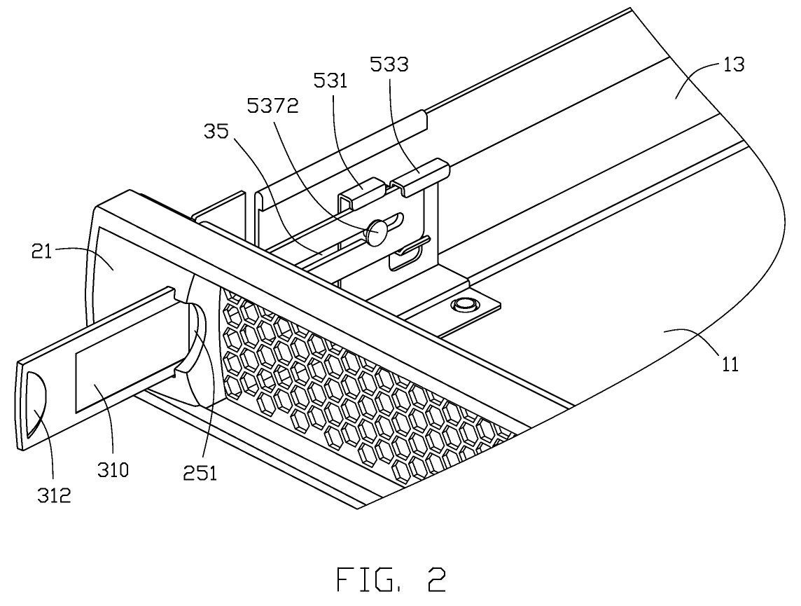

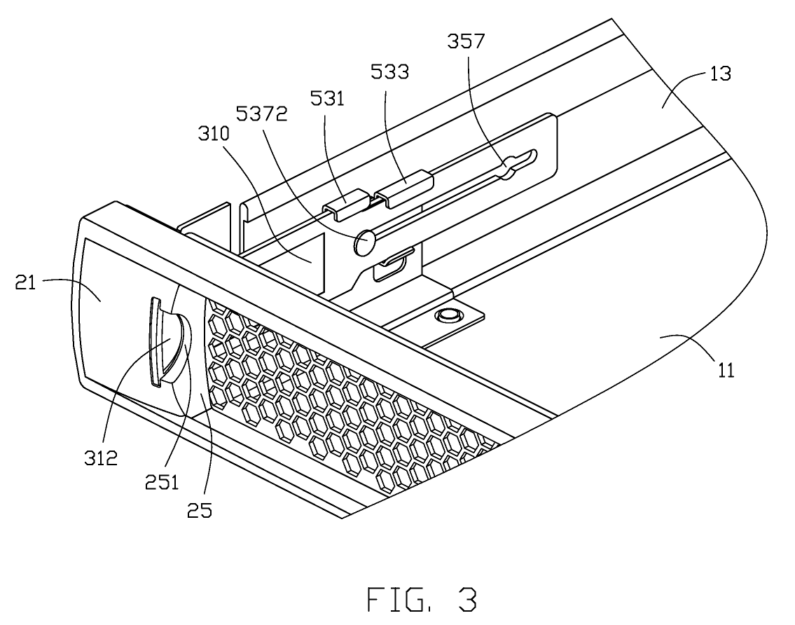

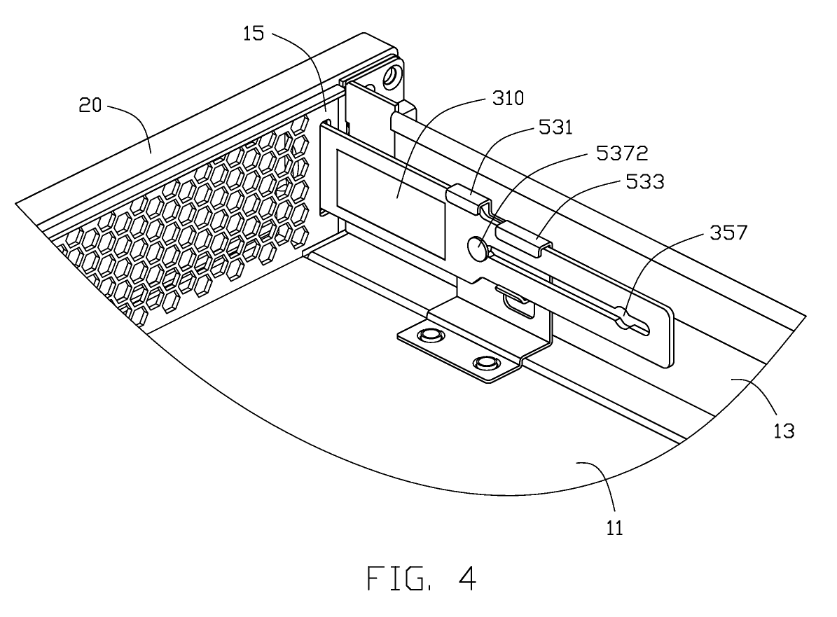

Referring to FIGS. 2-4, in assembly, the bezel 20 is secured on the front wall 15 of the chassis, with the second slot 211 in the bezel 20 aligned with the first slot 150 in the front wall 15 of the chassis 10, and the opening 23 corresponding to the heat dissipating area of the front wall 15. The mounting piece 33 of the ID case 30 is then inserted in the chassis 10 from the second slot 211 in the bezel 20. The mounting piece 33 slides along the sliding channel defined by the bent tab 533 and the supporting tab 535 and received therebetween. When the securing post 537 is aligned with the installing area 357 of the sliding slot 35, the mounting piece 33 is leaned so that the blocking portion 5372 of the securing post 537 engages into the sliding slot 35. When the ID case 30 is entirely received in the chassis 10, the sliding portion 5370 of the securing post 537 is tightly received in the receiving portion 351 of the sliding slot 35 and blocked by the blocking protrusions 353. Thus, the ID case 30 is mounted in the chassis 10. The end of the information piece 31 of the sheeted ID case 30 is aligned with the outer surface of the front panel 21 of the bezel 20. The operating piece 312 is exposed to the outside from the arc-shaped cutout 251 of the side plate 25, so that users may pull the ID case 30 out by a finger fitting in the recessed operating piece 312. Thus, the information piece 31 may be pulled out of the chassis 10 to expose the information of the server.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. A blade enclosure, comprising:
a chassis comprising a sidewall and a front wall substantially perpendicular to the sidewall;
a mounting bracket secured on the sidewall of the chassis; and
an ID case mounted in the chassis and substantially parallel to the sidewall of the chassis, the ID case comprising an information piece and a mounting piece extending from one end of the information piece, wherein a sliding channel is defined in the mounting bracket to receive the mounting piece of the ID case; a first slot aligned with the sliding channel is defined in the front wall for the ID case to slide into the chassis therefrom; the information piece is capable of being exposed outside of the chassis.

2. The blade enclosure of claim 1, wherein a securing post located in the sliding channel protrudes from the sidewall of the chassis; a sliding slot for the securing post to slide therealong is defined in the mounting piece of the ID case.

3. The blade enclosure of claim 2, wherein the securing post comprises a cylinder sliding portion sliding in the sliding slot and a rounded blocking portion blocked against an upper edge and a lower edge of the sliding slot.

4. The blade enclosure of claim 2, wherein a receiving portion is defined at one end of the sliding slot adjacent to the information piece to receive the sliding portion of the securing post, two blocking protrusions respectively extend from opposite edges of the sliding slot to block the sliding portion of the securing post in the receiving portion of the sliding slot.

5. The blade enclosure of claim 4, wherein two arc-shaped cutouts are respectively defined at two opposite edges of the sliding slot adjacent to the other end of the sliding slot, the two arc-shaped cutouts and the sliding slot cooperatively define an installing area to allow the blocking portion of the securing post to engage in the sliding slot.

6. The blade enclosure of claim 1 further comprising a bezel secured to the front panel of the chassis, the bezel comprising a front panel substantially parallel to the front wall of the chassis and a side plate connected to the front panel; a second slot corresponding to the first slot in the front wall of the chassis is defined in the front panel.

7. The blade enclosure of claim 6, wherein a cutout communicating with the second slot is defined at a joint of the front panel and the side plate; a recessed operating portion is defined at an end of the information piece and is exposed to the outside from the cutout of the side plate.

8. The blade enclosure of claim 1, wherein a supporting tab and a bent tab opposite to the supporting tab extend from the mounting bracket; the supporting tab and the bent tab cooperatively define the sliding channel for the ID case to slide therealong.

9. A blade enclosure, comprising:
a chassis comprising a sidewall and a front wall substantially perpendicular to the sidewall;
a mounting bracket secured on the sidewall of the chassis;
a bezel secured to the front wall of the chassis, the bezel comprising a panel substantially parallel to the front wall of the chassis and a side plate connected to the panel, an opening being defined at a joint of the panel and the side plate; and
an ID case substantially parallel to the sidewall of the chassis and insertable in the chassis from the opening, the ID case comprising an information piece and a mounting piece extending from one end of the information piece, the mounting piece received in the mounting bracket and slid therein, wherein the information piece is aligned with an outer surface of the panel of the bezel and capable of being exposed to the outside from the opening of the bezel.

10. The blade enclosure of claim 9, wherein a securing post protrudes from the sidewall of the chassis; a sliding slot for the securing post to slide therealong is defined in the mounting piece of the ID case.

11. The blade enclosure of claim 10, wherein the securing post comprises a cylinder sliding portion sliding in the sliding slot and a rounded blocking portion blocked against an upper edge and a lower edge of the sliding slot.

12. The blade enclosure of claim 10, wherein a receiving portion is defined at one end of the sliding slot adjacent to the information piece to receive the sliding portion of the securing post, two blocking protrusions respectively extend from opposite edges of the sliding slot to block the sliding portion of the securing post in the receiving portion of the sliding slot.

13. The blade enclosure of claim 12, wherein two cutouts are respectively defined at two opposite edges of the sliding slot adjacent to the other end of the sliding slot, the two cutouts and the sliding slot cooperatively define an installing area to allow the blocking portion of the securing post to engage in the sliding slot.

14. The blade enclosure of claim 9, wherein a first slot is defined in the front panel of the chassis, a second slot corresponding to the first slot is defined in the panel of the bezel, an arc-shaped cutout communicating with the second slot is defined in the side plate; the second slot and the arc-shaped cutout cooperatively define the opening; a recessed operating portion is formed at an end of the information piece and exposed outside from the cutout of the side plate.

15. The blade enclosure of claim 9, wherein a supporting tab and a bent tab opposite to the supporting tab extend from the mounting bracket and cooperatively define a sliding channel for the ID case to slide therealong.
